(19) United States
(12) Patent Application Publication
(10) Pub. No.: US 2021/0175858 A1
(43) Pub. Date: Jun. 10, 2021

(54) RADIO TRANSCEIVER ARRANGEMENT AND METHOD

(71) Applicant: Telefonaktiebolaget LM Ericsson (publ), Stockholm (SE)

(72) Inventors: Youping SU, Täby (SE); Yuanjun XU, Solna (SE); Zhongwen LI, Upplands Väsby (SE)

(21) Appl. No.: 17/257,051

(22) PCT Filed: Jul. 3, 2018
(86) PCT No.: PCT/SE2018/050725

§ 371 Date: Dec. 30, 2020

(51) Int. Cl. H03F 1/32; H04B 1/04; H03F 3/24

(52) U.S. Cl. CPC H03F 1/3247; H03F 3/245; H04B 1/0475

(57) ABSTRACT

A method for performing transmission and reception of signals in a radio transceiver arrangement includes creating a first analogue signal to be transmitted based on a digitally predistorted digital input signal and converting a second analogue signal into a digital output signal. The second analogue signal is a combination of a received signal and a transmitter observation signal. The received signal is based on a radio signal received by the radio transceiver arrangement. The transmitter observation signal is based on a tapped signal of the first analogue signal. The digital predistortion of the digital input signal is adapted based on the part of the output digital signal that corresponds to the transmitter observation signal.

### TECHNICAL FIELD

The proposed technology generally relates to radio transceiver arrangements and methods for performing transmission and reception of signals in a radio transceiver arrangement.

### BACKGROUND

The demands for high data rates and broadband wireless access necessitate the deployment of wireless radio systems using wide- and multi-band signals with advanced modulations. The higher order modulation has an advantage of high spectral efficiency but implies rapidly varying envelope and high peak-to-average power ratio (PAR).

To deploy these types of systems, radio frequency (RF) transmitters face several challenges in maintaining high power efficiency with lower acceptable distortions, i.e. good signal fidelity. The power amplifiers (PA) are the main contributors to the system power consumption and the nonlinearity of the RF transmitters.

Digital pre-distortion (DPD) techniques are widely deployed methods to enable PAs to operate efficiently and at the same time guarantee the required linearity and spurious emissions requirement. DPD alters the signal in the digital domain before it is fed to a digital-analogue converter and becomes amplified. The DPD compensates the amplifier's nonlinearity in order to produce a cleaner output signal. DPD systems operate in the digital domain, enabling engineers to build flexible and adaptive solutions that produce the desired output signal.

The transmitter observation receiver (TOR) is required for an appropriate DPD function. It converts the PA output from RF analogue domain back to the digital domain as part of a DPD feedback loop. The TOR needs to acquire a multiple of the transmitter's bandwidth for the intermodulation products to be linearized. This implies that a high speed Analogue-to-Digital Converter (ADC) is essential to cover such wide bandwidth.

The performance potential of beamforming techniques tends to increase with increasing number of antennas, since the baseband can take advantage of the available spatial freedom. This is facilitated by techniques for active antenna systems (AAS). 100 or more antenna elements may be used for various benefits. However, if DPD is to be implemented per antenna branch in an AAS the power and cost overheads of a dedicated TOR is obviously too expensive.

A TOR-sharing among different Transmitter (TX) branch is an alternative to lower the associated cost and power consumption. However, such an approach will reduce the availability of DPD to each transmitter branch, which often results in a sacrifice of performance comprising reduced tracking capability for dynamic traffic.

### SUMMARY

It is an object to provide a way to enable efficient digital pre-distortion in an active antenna system.

This and other objects are met by embodiments of the proposed technology.

According to a first aspect, there is provided a method for performing transmission and reception of signals in a radio transceiver arrangement. A first analogue signal to be transmitted from the radio transceiver arrangement is created based on a digitally predistorted digital input signal. A second analogue signal is converted into a digital output signal. The second analogue signal is a combination of a received signal and a transmitter observation signal. The received signal is based on a radio signal received by the radio transceiver arrangement. The transmitter observation signal is based on a tapped signal of the first analogue signal to be transmitted from the radio transceiver arrangement. The digitally predistortion of the digital input signal is adapted based on the part of the output digital signal that corresponds to the transmitter observation signal.

According to a second aspect, there is provided a radio transceiver arrangement. The radio transceiver arrangement is configured to create a first analogue signal to be transmitted from the radio transceiver arrangement based on a digitally predistorted digital input signal. The radio transceiver arrangement is further configured to convert a second analogue signal into a digital output signal. The second analogue signal is a combination of a received signal and a transmitter observation signal. The received signal is based on a radio signal received by the radio transceiver arrangement. The transmitter observation signal is based on a tapped signal of the first analogue signal to be transmitted from the radio transceiver arrangement. The digitally predistortion of the digital input signal is adapted based on the part of the output digital signal that corresponds to the transmitter observation signal.

According to a third aspect, there is provided a network node in a radio communication network. The network node is configured for operating with an active antenna system. The network node comprises a radio transceiver arrangement according to the second aspect for each independent branch in the active antenna system.

According to a fourth aspect, there is provided a user equipment. The user equipment is configured for operating with an active antenna system. The user equipment comprises a radio transceiver arrangement according to the second aspect for each independent branch in the active antenna system.

An advantage of the proposed technology is that there are no cost overheads for TOR ADC. Another advantage of the proposed technology is that there are no power overheads for TOR ADC. Yet another advantage of the proposed technology is that there is no performance sacrifice for DPD performance. In addition, the total size of the radio interface can be made smaller.

Other advantages will be appreciated when reading the detailed description.

### BRIEF DESCRIPTION OF THE DRAWINGS

The embodiments, together with further objects and advantages thereof, may best be understood by making reference to the following description taken together with the accompanying drawings, in which:

FIG. 1 is a schematic illustration of the ideas behind digital pre-distortion;

FIG. 2 is a schematic block illustration of an example of a radio transceiver arrangement;

FIG. 3 is a schematic block illustration of a radio transceiver arrangement for an active antenna systems;

FIG. 4 is a schematic block illustration of an embodiment of a radio communication system;

FIG. 5 is a schematic block illustration of an embodiment of a radio transceiver arrangement with a common ADC for direct sampling of a received radio signal and a TOR signal;

FIG. 6 is a schematic flow diagram illustrating steps of an embodiment of a method for performing transmission and reception of signals in a radio transceiver arrangement;

FIG. 7 is a schematic flow diagram illustrating steps of another embodiment of a method for performing transmission and reception of signals in a radio transceiver arrangement;

FIG. 8 is a schematic block illustration of an embodiment of a radio transceiver arrangement with a common ADC for direct RF-sampling of a received radio signal and a heterodyne TOR signal;

FIG. 9 is a spectrum diagram for direct receiver RF-sampling and heterodyne TOR;

FIG. 10 is a schematic block illustration of an embodiment of a radio transceiver arrangement with a common ADC for direct RF-sampling of a received radio signal and a direct RF-sampling of a TOR signal;

FIG. 11A is an example of a spectrum diagram for direct receiver RF-sampling and direct RF-sampling TOR;

FIG. 11B is another example of a spectrum diagram for direct receiver RF-sampling and direct RF-sampling TOR;

FIG. 12 is a schematic block diagram illustrating an embodiment of a network node based on a hardware circuitry implementation;

FIG. 13 is a schematic block diagram illustrating an embodiment of a user equipment based on a hardware circuitry implementation;

FIG. 14 is a schematic block diagram illustrating another embodiment of a network node based on combination of both processor and hardware circuitry;

FIG. 15 is a schematic block diagram illustrating another embodiment of a user equipment based on combination of both processor and hardware circuitry;

FIG. 16 is a schematic block diagram illustrating an embodiment of a network device; and

FIG. 17 is a schematic diagram illustrating an embodiment of a radio transceiver arrangement.

### DETAILED DESCRIPTION

Throughout the drawings, the same reference designations are used for similar or corresponding elements.

For a better understanding of the proposed technology, it may be useful to begin with a brief overview of the basic DPD and AAS methods and devices.

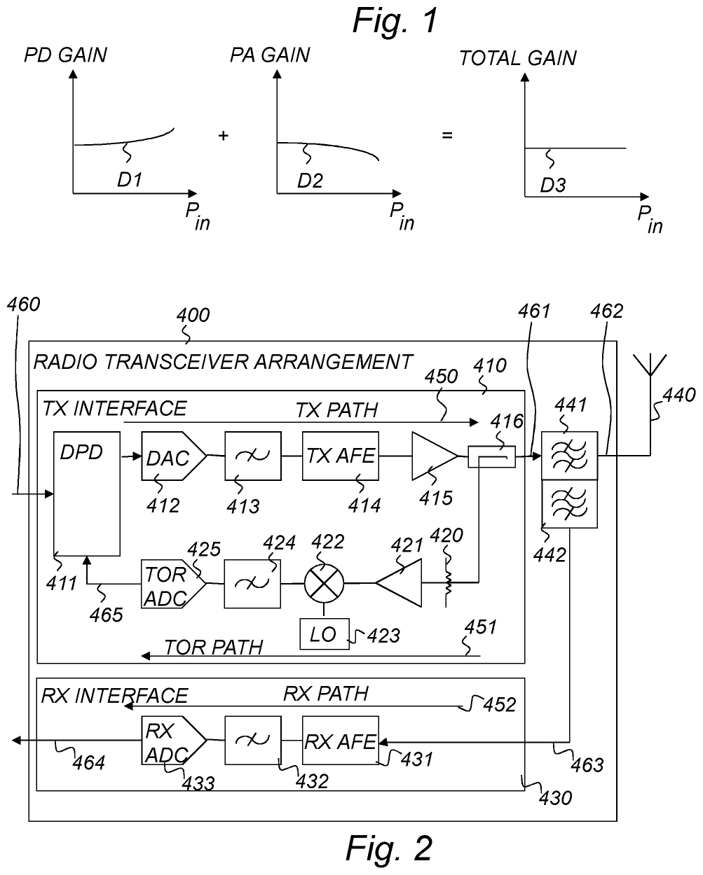

As mentioned above, DPD function basically digitally distort a signal in order to compensate for a predicted nonlinear power amplification at a later stage. FIG. 1 illustrates schematically the ideas behind DPD. A pre-distorter (PD) is configured to have a certain gain, typically dependent on the magnitude of the input power. The PD is given a pre-distorter gain characteristics e.g. according to the diagram D1. The PA has an intrinsic gain characteristics according to the diagram D2. Together, these gains are combined into a total gain, as illustrated in diagram D3. The aim for the PD is thus to provide a constant total gain of the amplified output signal with reference to the original signal.

Applying DPD typically require that a TOR is available. The TOR provides a feedback of the actual amplified signal to enable the DPD to be adapted accordingly. The TOR can use heterodyne, homodyne or direct RF-sampling architecture. In heterodyne sampling architecture, the frequency is shifted into an intermediate frequency (IF). In a homodyne sampling architecture, the modulation of the RF signal is shifted to zero frequency. In a direct RF-sampling architecture, the, TOR operated directly on the RF signal.

In FIG. 2 an example of a radio transceiver arrangement 400 comprising a heterodyne TOR architecture is illustrated. In a transmission (TX) path 450 of a transmitter TX interface 410, an input signal 460 intended to be transmitted is obtained as in input to a DPD 411. The DPD 411 performs its pre-distortion and provides a digitally pre-distorted digital input signal to a digital-to-analogue converter 412 (DAC), in which the digitally pre-distorted digital input signal is converted into a corresponding analogue signal. This analogue signal is typically filtered in a filter 413 and provided to a TX analogue front end (AFE) unit 414 according to conventional procedures. The signal from the TX AFE 414 is provided to a power amplifier (PA) 415 to be amplified into an analogue signal 461 to be transmitted. This signal may typically be bandpass filtered in a transmitter filter 441 to provide the analogue signal 462 to be output from the radio transceiver arrangement 400 to an antenna 440. The TX path may have a heterodyne, homodyne or direct RF architecture.

In order to support the DPD, the radio transceiver arrangement 400 typically also comprises a TOR path 451. A coupler device 416 is arranged to obtain a tapped signal being copy of the analogue signal 461 to be transmitted, i.e. the signal outputted from the PA 415. The tapped signal may be attenuated in an attenuator 420 or amplified in an amplifier 421. In the present example, the TOR architecture is of a heterodyne architecture and the attenuated and/or amplified tapped signal is mixed in a mixer 422 with a signal from a local oscillator (LO) 423. The desired channel is mixed into an IF via the mixer 422 and the full bandwidth of all the intermodulation products is captured. The exact IF is typically selected to simplify filtering and frequency planning. A filter 424, typically a bandpass filter, filters the mixed signal in order to suppress unwanted signal components and provides a transmitter observation signal. The transmitter observation signal is input into a TOR analogue-to-digital converter (ADC) 425 providing an output digital signal 465 corresponding to the transmitter observation signal. The output digital signal 465 is provided to the DPD 411 in order to enable an adaption of the digital predistortion based on the feed-back information provided by the output digital signal 465.

The radio transceiver arrangement 400 has typically also a receiver (RX) interface 430. The receiver path 452 starts from a radio signal received by the radio transceiver arrangement 400. A bandpass filter 442 filters out the frequency range corresponding to the received signal 463. This signal is provided to a RX AFE 431, which operates according to conventional procedures. The signal is thereafter typically filtered in a filter 432 before it is provided to a RX ADC 433. The RX ADC 433 outputs a digital signal 464 based on the received radio signal 463.

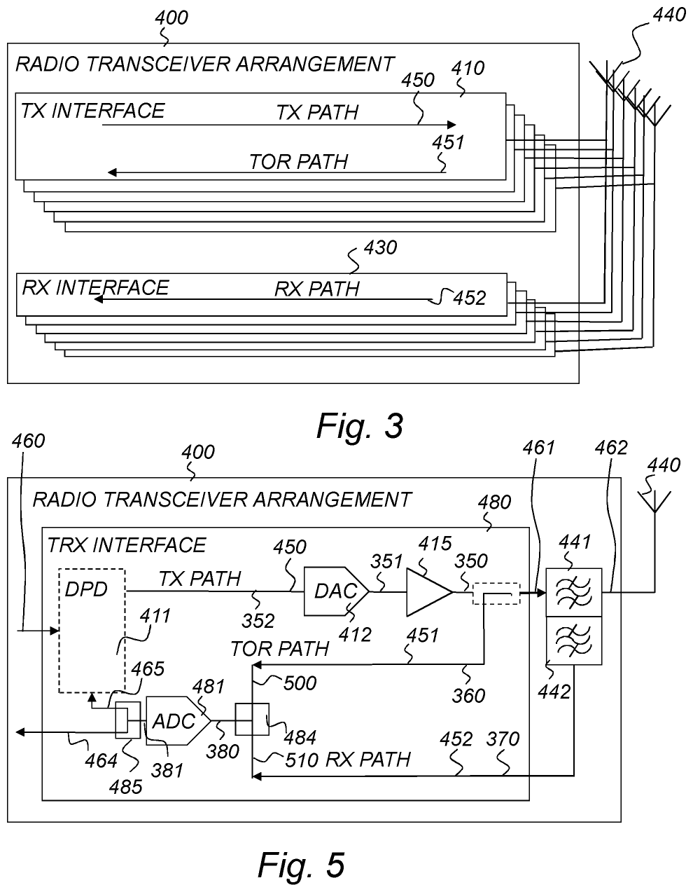

In AAS, the radio is typically integrated to offer possibilities for fine grained digital control of the beamforming weight of each individual sub element within the antenna group. Massive Multiple-Input Multiple-Output (MIMO) is the back-bone for New Radio (NR) or 5th Generation (5G) network where 100 or more antenna elements are used for various benefits. Using an AAS that combines the antennas and the RF transceiver (TRX) unit including transmitter and receiver chains, into one unit is an effective way to resolve these issues. FIG. 3 illustrates schematically such a situation. However, AAS radio must overcome some technical challenges to reach its full potential. Equipment vendors are striving to improve the performance of their radio systems whilst making them more site friendly and more efficient.

As mentioned before, deployment of wide-/multi-band signals require a wideband TOR with high-speed ADC and flat frequency response over a wide range of frequencies. This is particularly important for capturing accurate measurement data essential for the identification of the DPD coefficients. For AAS radio, which possibly has 100 or more transmitter paths, the power and cost overheads of a dedicated TOR ADC is obviously too expensive. The significant power and cost overheads of high-speed ADC thus brings down the overall efficiency of the transmitter. Thus, it limits the usability of the DPD as approach to enhance the efficiency and linearity.

The core of the new solution is make a cost-effective and compact FDD AAS radio.

We will start with an overview of a typical system in which the present ideas may be implemented. Although the subject matter described herein may be implemented in any appropriate type of system using any suitable components, the embodiments disclosed herein are described in relation to a wireless network, such as the example wireless network illustrated in FIG. 4. For simplicity, the wireless network of FIG. 4 only depicts network 110, network nodes 30, and user equipment (UE) 50. In practice, a wireless network may further include any additional elements suitable to support communication between UEs or between a UE and another communication device, such as a landline telephone, a service provider, or any other network node or end device. Of the illustrated components, network node 30 and UE 50 are depicted with additional detail. The wireless network may provide communication and other types of services to one or more wireless devices to facilitate the wireless devices' access to and/or use of the services provided by, or via, the wireless network.

The wireless network may comprise and/or interface with any type of communication, telecommunication, data, cellular, and/or radio network or other similar type of system. In some embodiments, the wireless network may be configured to operate according to specific standards or other types of predefined rules or procedures. Thus, particular embodiments of the wireless network may implement communication standards, such as Global System for Mobile Communications (GSM), Universal Mobile Telecommunications System (UMTS), Long Term Evolution (LTE), and/or other suitable 2G, 3G, 4G, or 5G standards; wireless local area network (WLAN) standards, such as the IEEE 802.11 standards; and/or any other appropriate wireless communication standard, such as the Worldwide Interoperability for Microwave Access (WiMax), Bluetooth, ZWave and/or ZigBee standards.

Network 110 may comprise one or more backhaul networks, core networks, IP networks, public switched telephone networks (PSTNs), packet data networks, optical networks, wide-area networks (WANs), local area networks (LANs), wireless local area networks (WLANs), wired networks, wireless networks, metropolitan area networks, and other networks to enable communication between devices.

Network node 30 and UE 50 comprise various components described in more detail below. These components work together in order to provide network node and/or wireless device functionality, such as providing wireless connections in a wireless network. In different embodiments, the wireless network may comprise any number of wired or wireless networks, network nodes, base stations, controllers, wireless devices, relay stations, and/or any other components or systems that may facilitate or participate in the communication of data and/or signals whether via wired or wireless connections.

In FIG. 4, network node 30 includes a radio transceiver arrangement 400. The radio transceiver arrangement 400 typically comprises functionalities for the transmission and reception of radio signals. In a typical case, the radio transceiver arrangement 400 comprises processing circuitry and an interface to one or more antenna 31. The network node 30 further typically comprises additional components, such as device readable medium, auxiliary equipment, a power source and a power circuit. Although network node 30 illustrated in the example of FIG. 4 may represent a device that includes the illustrated combination of hardware components, other embodiments may comprise network nodes with different combinations of components. It is to be understood that a network node comprises any suitable combination of hardware and/or software needed to perform the tasks, features, functions and methods disclosed herein. Network node 30 may be composed of multiple physically separate components (e.g., a NodeB component and a RNC component, or a BTS component and a BSC component, etc.), which may each have their own respective components. In certain scenarios in which network node 30 comprises multiple separate components (e.g., BTS and BSC components), one or more of the separate components may be shared among several network nodes. For example, a single RNC may control multiple NodeB's. In such a scenario, each unique NodeB and RNC pair, may in some instances be considered a single separate network node. In some embodiments, network node 30 may be configured to support multiple radio access technologies (RATs). In such embodiments, some components may be duplicated and some components may be reused.

The processing circuitry is typically configured to perform any determining, calculating, or similar operations (e.g., certain obtaining operations) described herein as being provided by a network node. These operations performed by processing circuitry may include processing information obtained by processing circuitry by, for example, converting the obtained information into other information, comparing the obtained information or converted information to information stored in the network node, and/or performing one or more operations based on the obtained information or converted information, and as a result of said processing making a determination. The processing circuitry may comprise a combination of one or more of a microprocessor, controller, microcontroller, central processing unit, digital signal processor, application-specific integrated circuit, field programmable gate array, or any other suitable computing device, resource, or combination of hardware, software and/or encoded logic operable to provide, either alone or in conjunction with other network node components, such as the device readable medium.

In some embodiments, the processing circuitry may include one or more of radio frequency (RF) transceiver circuitry and baseband processing circuitry.

The interface is used in the wired or wireless communication for signalling and/or sending data between network nodes 30, the network 110, and/or UEs 50. The interface comprises port(s)/terminal(s) to send and receive data, for example to and from network 110 over a wired connection 111. Interface also typically includes radio front end circuitry that may be coupled to, or in certain embodiments a part of, the antenna(s) 31.

The antenna system may include one or more antennas 31, or antenna arrays, configured to send and/or receive wireless signals. Antenna 31 may be coupled to the radio front end circuitry may be any type of antenna capable of transmitting and receiving data and/or signals wirelessly using an active antenna system, as has been described further above.

As used herein, user equipment (UE) refers to a device capable, configured, arranged and/or operable to communicate wirelessly with network nodes and/or other wireless devices. Unless otherwise noted, the term UE may be used interchangeably herein with Wireless Device (WD). In some embodiments, a WD may be configured to transmit and/or receive information without direct human interaction. For instance, a WD may be designed to transmit information to a network on a predetermined schedule, when triggered by an internal or external event, or in response to requests from the network. Examples of a UE include, but are not limited to, a smart phone, a mobile phone, a cell phone, a voice over IP (VoIP) phone, a wireless local loop phone, a desktop computer, a personal digital assistant (PDA), a wireless cameras, a gaming console or device, a music storage device, a playback appliance, a wearable terminal device, a wireless endpoint, a mobile station, a tablet, a laptop, a laptop-embedded equipment (LEE), a laptop-mounted equipment (LME), a smart device, a wireless customer-premise equipment (CPE), a vehicle-mounted wireless terminal device, etc. A WD may support device-to-device (D2D) communication, for example by implementing a 3GPP standard for sidelink communication, vehicle-to-vehicle (V2V), vehicle-to-infrastructure (V21), vehicle-to-everything (V2X) and may in this case be referred to as a D2D communication device. As yet another specific example, in an Internet of Things (IoT) scenario, a WD may represent a machine or other device that performs monitoring and/or measurements, and transmits the results of such monitoring and/or measurements to another WD and/or a network node. The WD may in this case be a machine-to-machine (M2M) device, which may in a 3GPP context be referred to as an MTC device. As one particular example, the WD may be a UE implementing the 3GPP narrow band internet of things (NB-IoT) standard. Particular examples of such machines or devices are sensors, metering devices such as power meters, industrial machinery, or home or personal appliances (e.g. refrigerators, televisions, etc.) personal wearables (e.g., watches, fitness trackers, etc.). In other scenarios, a WD may represent a vehicle or other equipment that is capable of monitoring and/or reporting on its operational status or other functions associated with its operation. A UE as described above may represent the endpoint of a wireless connection, in which case the device may be referred to as a wireless terminal. Furthermore, a UE as described above may be mobile, in which case it may also be referred to as a mobile device or a mobile terminal.

As illustrated, the UE 50 includes one or more antennas 51 and a radio transceiver arrangement 400. The radio transceiver arrangement 400 typically comprises an interface, processing circuitry, device readable medium, user interface equipment, auxiliary equipment, a power source and a power circuitry. UE 50 may include multiple sets of one or more of the illustrated components for different wireless technologies supported by UE 50, such as, for example, GSM, WCDMA, LTE, NR, WiFi, WiMAX, or Bluetooth wireless technologies, just to mention a few. These wireless technologies may be integrated into the same or different chips or set of chips as other components within UE.

The antenna 51 may include one or more antennas or antenna arrays, configured to send and/or receive wireless signals, and is typically connected to an interface in the radio transceiver arrangement 400. In certain alternative embodiments, antenna 51 may be separate from UE 50 and be connectable to UE 50 through an interface or port. The antenna 51 and the radio transceiver arrangement 400 may be configured to perform any receiving or transmitting operations described herein as being performed by a UE. Any information, data and/or signals may be received from a network node and/or another UE. In some embodiments, radio front end circuitry and/or antenna 51 may be considered as an interface.

The interface may comprise the radio front end circuitry. The radio front end circuitry may comprise one or more filters and amplifiers and is typically connected to the antenna 51 and the processing circuitry and is configured to condition signals communicated between the antenna 51 and the processing circuitry.

The proposed technology herein is to use one common RF-sampling ADC for the normal receiver and for the DPD TOR.

A new class of direct RF-sampling ADCs is being designed in advanced CMOS processes that allow much higher conversion rates with lower power consumption than some previous generations. Furthermore, this design approach also enables more digital integration, which is used for a low-power, multi-gigabit serial interface and on-chip digital down conversion (DDC). Combined, they make for a very size- and power-efficient digital interconnect between the data converter and digital processor.

In a direct RF-sampling receiver architecture, the data converter digitizes a large chunk of frequency spectrum directly at RF and hands it off to a signal processor to dissect the available information. This is a paradigm shift that takes what has traditionally been handled by analogue processing, e.g. mixers, local oscillators and their attendant filters and amplifiers, into the digital domain.

For the RF sampling ADC, the sampling frequency is usually many time of the operating RX bandwidth. Thus, the Nyquist frequency or usable frequency range is much larger than the traditional ADC can offer. This provides an opportunity to use a single ADC to sample both RX and DPD TOR data by appropriate frequency planning. To avoid the aliasing products to disturb the signal, the signal into ADC needs to be carefully planned and filtered. Depending on the specific applications, in the RX path, a filter will be chosen to suppress the TOR signal, so it is low enough that the RX signal SNR will not be noticeably degraded, to guarantee RX performance. Similarly, in the TOR path, the RX signal shall be suppressed so that the TOR signal SNR will not be noticeably degraded, to guarantee the required DPD performance. The RX signal includes both the wanted RX signal and unwanted blocking interference signal.

In one embodiment of a radio transceiver arrangement, the radio transceiver arrangement configured to create a first analogue signal to be transmitted from the radio transceiver arrangement based on a digitally predistorted digital input signal, and to convert a second analogue signal into a digital output signal. The second analogue signal is a combination of a received signal and a transmitter observation signal. The received signal is based on a radio signal received by the radio transceiver arrangement. The transmitter observation signal is based on a tapped signal of the first analogue signal to be transmitted the said radio transceiver arrangement. The digitally predistortion of the digital input signal is adapted based on the part of the output digital signal that corresponds to the transmitter observation signal.

A particular embodiment of a radio transceiver arrangement comprises a digital-to-analogue converter having an input for the digitally predistorted digital input signal and a power amplifier directly or indirectly connected to an output of the digital-to-analogue converter. The power amplifier has an output for the first analogue signal. The radio transceiver arrangement further comprises an analogue-to-digital converter having an input for the second analogue signal and an output for the digital output signal.

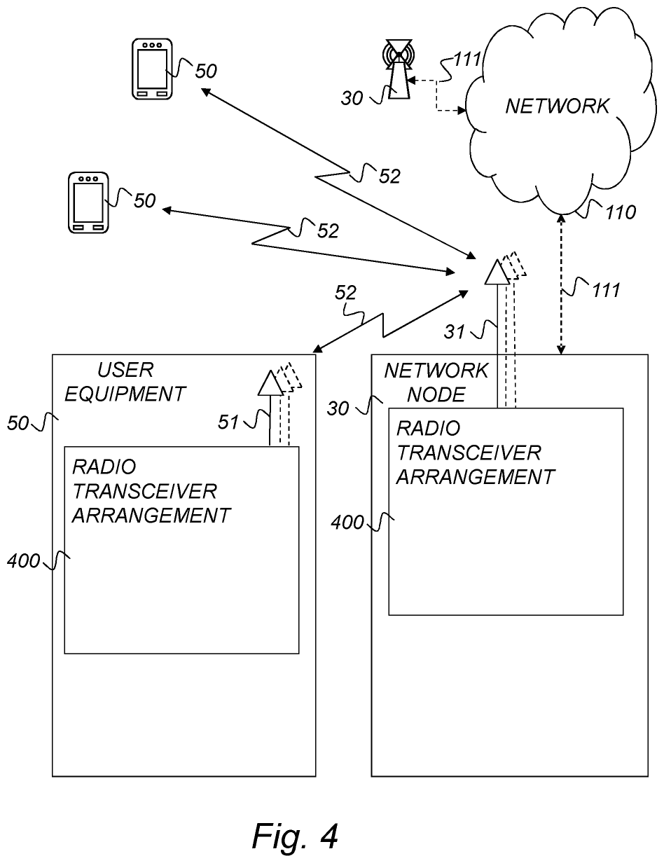

FIG. 5 illustrates schematically an embodiment of a radio transceiver arrangement 400. The radio transceiver arrangement 400 comprises a transceiver interface 480. The transceiver interface 480 receives, at an input, a digital input signal 460 intended to be transmitted from the radio transceiver arrangement 400.

The digital input signal 460 is typically provided to a Digital pre-distortion module 411, giving a digitally predistorted digital input signal 352 of a transmitter path 450 as output, which is adapted to the characteristics of the later used power amplifier 415. The digital pre-distortion may also be provided outside the transceiver interface and/or radio transceiver arrangement, and in such cases, the received digital input signal 460 can be used directly as the digitally predistorted digital input signal 352 of the transmitter path 450. The digitally predistorted digital input signal 352 is converted in a digital-to-analogue converter (DAC) 412 in to a low power analogue signal 351. This low power analogue signal 351 is provided to a power amplifier 415 for amplification to a power suitable for transmission. The output from the power amplifier 415 constitutes a first analogue signal 350 to be transmitted 461. These parts of the transceiver interface 480 thereby constitutes a transmitter path of the transceiver interface.

The transceiver interface 480 thus provides, based on the digital input signal 460, the first analogue signal 350. The first analogue signal 350 is typically filtered in an output filter 441, typically a bandpass filter, into a filtered analogue signal 462 which is provided to an antenna 440 or antenna system for the actual transmission.

The transceiver interface 480 also has a receiver path. An analogue signal 462 corresponding to a radio signal received by the antenna 440 is provided as an input signal 370 of a receiver path 452 to the radio transceiver arrangement, typically filtered in an input filter 442, typically a bandpass filter. A received signal 510 based on the input signal is via a combiner 484, described later, provided to an analogue-to-digital converter (ADC) 481. An output 381 from the ADC 481 is via a splitter 485, described later, provided as an output received digital signal 464 from the radio transceiver arrangement 400.

In order to perform a well-adapted digital predistortion, a transmitter observation receiver (TOR) path 451 is also provided within the transceiver interface. A transmission observation signal 500 based on a signal 360 tapped from the first analogue signal 350 to be transmitted by the radio transceiver arrangement is provided to the combiner 484. In the combiner 484, the received signal and the transmission observation signal are combined into a second analogue signal 380. This second analogue signal 380 is provided to the ADC 481 for conversion into a digital signal 381. The conversion is thus performed jointly for the two parts of the combined signal. The digital signal 381 as outputted from the ADC 481 is therefore also a combination of the two components. However, since these components are separated in frequency, as will be discussed further below, the two components can be separated in a separator 485 in to the earlier mentioned output received digital signal 464 and a digital version 465 of the transmitter observation signal 500. The digitally predistortion of the digital input signal can therefore be adapted based on the part of the output digital signal from the ADC 481 that corresponds to the transmitter observation signal.

The radio transceiver arrangement can be part of a network node. Thus, according to an aspect of the proposed technology there is provided a network node comprising a radio transceiver arrangements as being described above.

The radio transceiver arrangement can be part of a user equipment. Thus, according to an aspect of the proposed technology there is provided a user equipment comprising a radio transceiver arrangements as being described above.

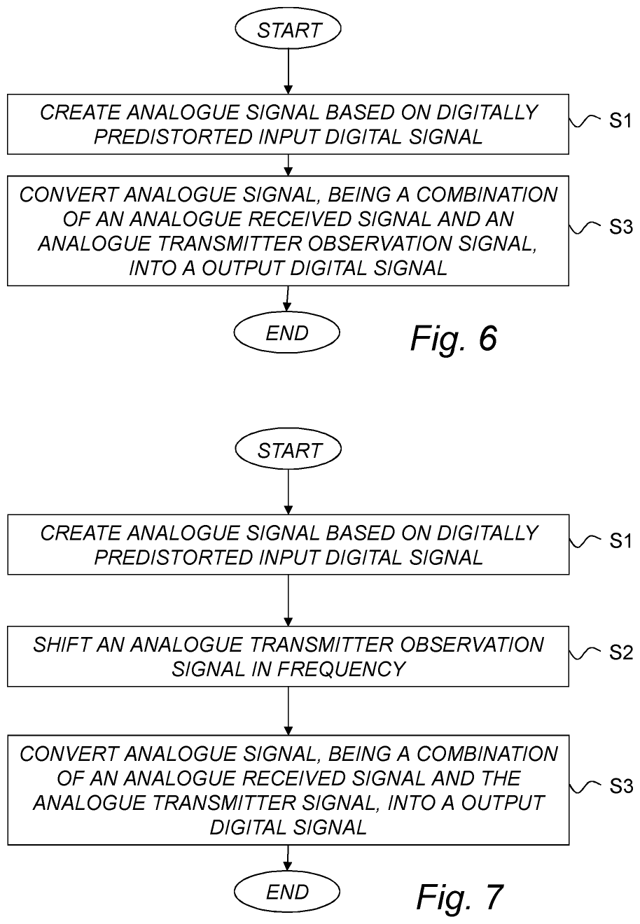

FIG. 6 is a schematic flow diagram illustrating steps of an embodiment of a method for performing transmission and reception of signals in a radio transceiver arrangement. In step S1, a first analogue signal to be transmitted from the radio transceiver arrangement is created based on a digitally predistorted digital input signal. In step S3, a second analogue signal is converting into a digital output signal. The second analogue signal is a combination of a received signal and a transmitter observation signal. The received signal is based on a radio signal received by the radio transceiver arrangement. The transmitter observation signal is based on a tapped signal of the first analogue signal to be transmitted from the radio transceiver arrangement. The digitally predistortion of the digital input signal is adapted based on the part of the output digital signal that corresponds to the transmitter observation signal.

Depending on the bandwidth of TX and RX operating band, and the duplex distance, there can be several solutions.

FIG. 7 is a schematic flow diagram illustrating steps of another embodiment of a method for performing transmission and reception of signals in a radio transceiver arrangement. The steps S1 and S3 are basically analogue to the ones presented above. In FIG. 7, a further step S2 is introduced, in which the transmitter observation signal is shifted in frequency range compared to the first analogue signal to be transmitted from the radio transceiver arrangement.

In one embodiment, the shifting is a heterodyne shifting.

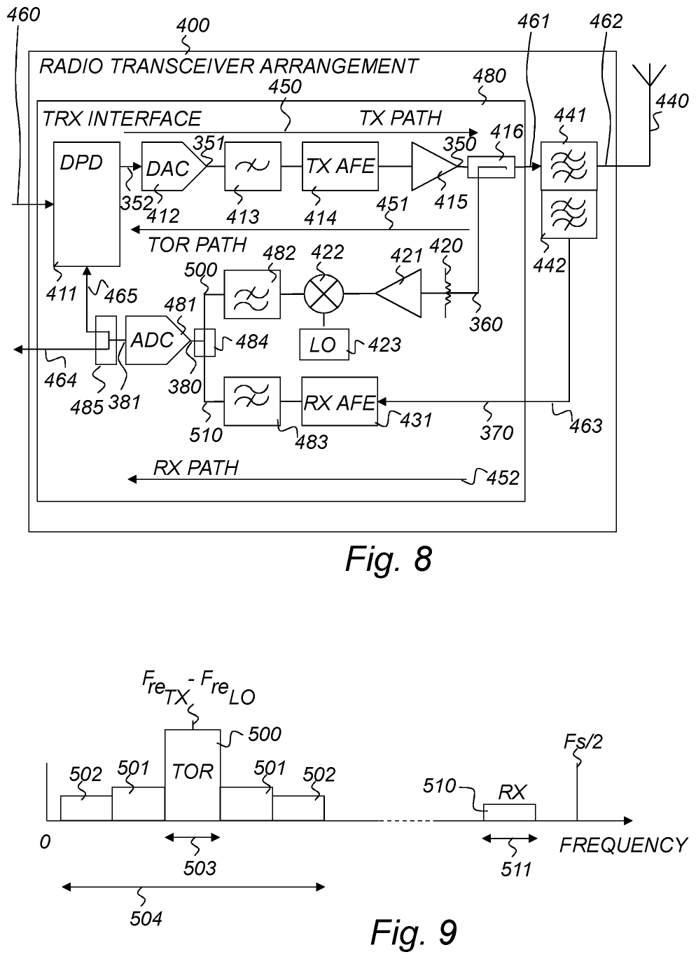

FIG. 8 is a schematic drawing of another embodiment of a radio transceiver arrangement 400. In the transmitter (TX) path 450, the digital input signal 460 is provided to a Digital pre-distorter 411 and the output therefrom is provided to the DAC 412. In other words, a digital predistorter 411 has an input for a digital input signal to be transmitted from the radio transceiver arrangement. The digital predistorter 411 also has an output for the digitally predistorted digital input signal and in input for the part 465 of the output digital signal that corresponds to the transmitter observation signal.

The analogue output from the DAC 412 may also in different embodiment be further treated before being amplified. In FIG. 8, this is exemplified by a filter 413 and a TX Analogue Front End (AFE) 414, performing typical signal conditioning procedures, as such, known in prior art. The transmitter path 450 can be of a heterodyne, homodyne or direct RF architecture.

In the receiver (RX) path 452, different signal conditioning operations can be performed in different embodiments. In the illustrated example, the RX path 452 comprises a RX AFE 431 and a high-pass filter 483. The receiver path 452 is of a direct RF-sampling receiver type. The RX path 452 may alternatively comprise a band-pass filter instead of the illustrated high-pass filter 483.

In the TOR path 451 of FIG. 8, a mixer 422 is provided. The mixer 422 uses a signal from a local oscillator (LO) 423 to shift the frequency for the signal tapped from the first analogue signal to be transmitted by the radio transceiver arrangement. The main frequency band of the shifted signal occurs at a frequency corresponding to the difference between the original reference frequency and the LO reference frequency. The TOR path 451 is thus of a heterodyne receiver character. The frequency-shifted signal is low-pass filtered in a low-pass filter 482 in order to suppress other components of the heterodyne shifting. The TOR path 451 may alternatively comprise a band-pass filter instead of the illustrated low-pass filter 482. The TOR path 451 may optionally comprise other typical signal treatment components, such as an attenuator 420 and/or an amplifier 421.

It can be noticed that there are individual anti-alias filters for the receiver path 452 and the TOR path 451. The frequency-shift and the filtering has the task to create the needed signal separation and allows further signal processing in digital domain. The receiver signal and TOR signal are then combined in the combiner 484. The combined signal is then sampled by the common RF sampling ADC 481.

In other words, the received signal and the transmitter observation signal are filtered to suppress aliasing products of the combination of the received signal and the transmitter observation signal.

This solution is typically used when the RX signal and TOR signal will overlap in frequency domain. By down-converting the TOR signal to a suitable intermediate frequency, it is possible to squeeze the RX signal and the down-converted TOR signal into same Nyquist zone of the RF sampling ADC 481.

In other words, in one embodiment, the radio transceiver comprises a frequency shifter operable to shift the transmitter observation signal in frequency range compared to the first analogue signal to be transmitted from the radio transceiver arrangement.

In one embodiment, the frequency shifter is a heterodyne shifter.

The ADC spectrum corresponding to such an embodiment is shown in FIG. 9 as the signal is placed in the 1st Nyquist zone. The received signal 510 has an operating frequency band 511 and occurs below half the sampling frequency Fₛ of the ADC. The down-converted TOR signal has a frequency of Fᵣₑ_{_{TX}}−Fᵣₑ_{_{LO}} comprises a central main signal 500 having an operating frequency band 503. Side bands 501, 502 corresponding to IM_3 and IM_5 signals, caused by the down-converting gives a total TOR bandwidth 504. The TOR signal 500 and the RX signal 510 can easily be separated and used for their respective purposes.

The diagram of FIG. 9 only shows the case of putting all signals in the first Nyquist zones of the ADC. However, in alternative embodiments, the signal can be in different Nyquist zones of the ADC as well

The filtered TOR signal will be fed to the DPD block. Depends on the DPD configuration, the TOR signal may be further filtered and frequency shifted for the DPD model extraction/adaption.

When using a common ADC for the normal RX as well as the TOR, the TOR signal may be a blocking interference to the RX signal and the RX signal may be a blocking interference to the TOR signal. When the TOR is blocked by the RX signal, then the DPD performance will be degraded. When the RX is blocked by the TOR signal, then the RX performance will be degraded. The above discussed shifting of the TOR signal is thus one possible solution.

Another option to mitigate the blocking problem, is to have optimized line-up allocation and frequency planning for both RX and TOR. To enable the ADC sharing between the RX and the DPD TOR, we may need frequency planning to achieve the necessary distance between the RX and the TOR spectrum to allow efficient analogue and digital filtering of the sampled signal. After filtering of the captured ADC signal, the RX signal will then be fed further to the RX chain for further signal processing and generating the AGC control indication.

Thus, in one embodiment, the radio transceiver arrangement operates with frequency division duplex. Preferably, a frequency division duplex distance is large enough for the transmitter observation signal and the analogue received signal not to overlap in the frequency domain.

In a further embodiment, the converting comprises direct radio frequency sampling of both the transmitter observation signal and the analogue received signal.

In a further embodiment, the received signal and the transmitter observation signal are filtered to suppress aliasing products of the combination of the received signal and the transmitter observation signal.

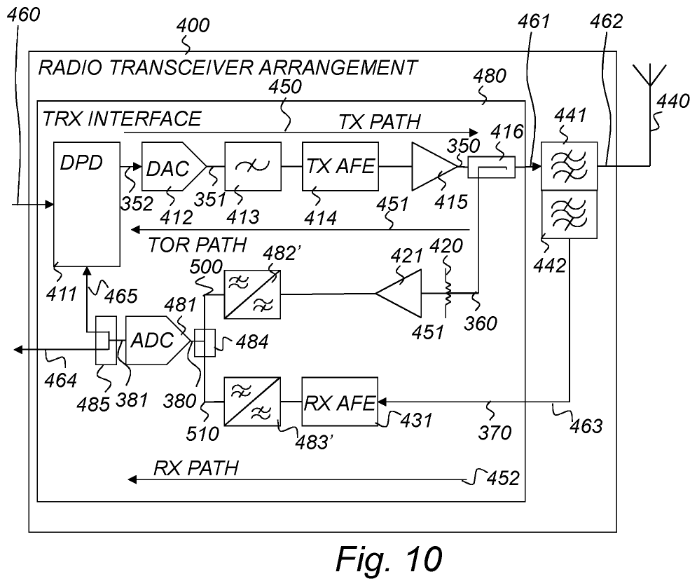

FIG. 10 illustrate an embodiment of a radio transceiver arrangement. The radio transceiver arrangement operates with large frequency division duplex distance. In this embodiment, a common ADC is used for direct RF-sampling of the receiver signal and direct RF-sampling of the TOR signal. A frequency division duplex distance is large enough for the transmitter observation signal and the analogue received signal not to overlap in the frequency domain.

In other words, the radio transceiver interface 480 of the radio transceiver arrangement 480 is configured for performing the converting as comprising direct radio frequency sampling of both the transmitter observation signal and the analogue received signal.

The transmitter path 450 can be of a heterodyne, homodyne or direct RF architecture. The receiver path 452 is of a direct RF-sampling type. The TOR path 451 is also of a direct RF-sampling type. There is individual anti-alias filters 483′ and 482′ for the receiver path 452 and the TOR path 451, respectively. The receiver signal and TOR signal are then combined in the combiner 484 and sampled by the common RF sampling ADC 481. The anti-alias filters 483′, 482′ for RX path 452 and TOR path 451 can be a low pass, or band pass filter to create the needed signal separation and filtering to allow further signal processing in digital domain. Note that this solution works only when the RX signal and filtered TOR signal do not overlap in frequency domain.

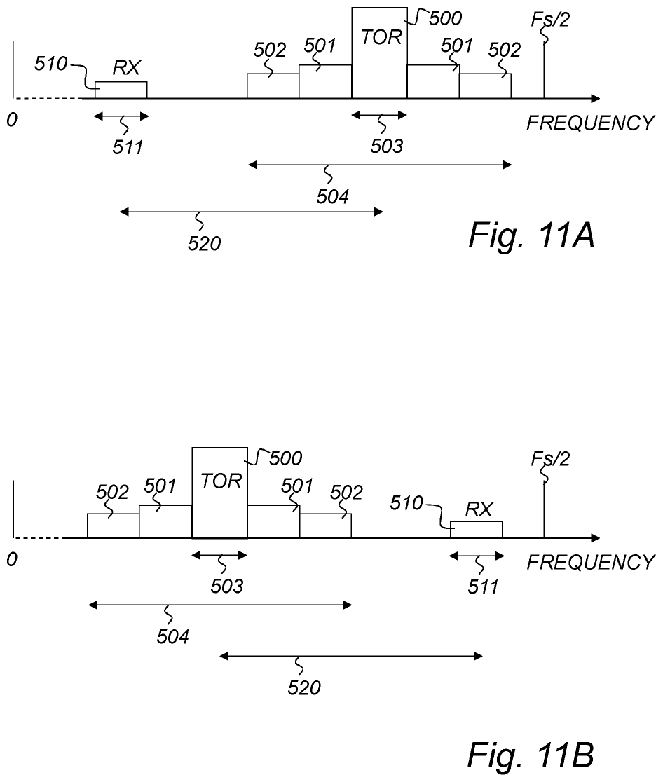

An ADC spectrum is shown in FIG. 11A. In this example, the RX signal is situated at lower frequencies compared to the TOR signal, having a large frequency division duplex distance 520 that ensures that they do not overlap.

The diagram of FIG. 11A only shows the case of putting all signals in the first Nyquist zones of the ADC. However, in alternative embodiments, the signal can be in different Nyquist zones of the ADC as well

Another ADC spectrum is shown in FIG. 11B. In this example, the RX signal is situated at lower frequencies compared to the TOR signal, having a large frequency division duplex distance 520 that ensures that they do not overlap.

The diagram of FIG. 11B only shows the case of putting all signals in the first Nyquist zones of the ADC. However, in alternative embodiments, the signal can be in different Nyquist zones of the ADC as well

Preferably, the frequency division duplex distance 520 should exceed half the sum of the widths 511, 504 of the RX and TOR signals.

The above described methods are intended to be usable e.g. in active antenna systems (AAS). In such applications, the creating and converting steps are preferably performed for each independent branch in the active antenna system.

The methods can also be performed both in uplink and downlink signalling. In one embodiment, the steps of creating the first analogue signal and converting the second analogue signal into the digital output signal are performed in a network node of a radio communication network.

In another embodiment, the steps of creating the first analogue signal and converting the second analogue signal into the digital output signal are performed in a user equipment.

As used herein, the non-limiting terms “User Equipment (UE)”, “station (STA)” and “wireless communication device” or “wireless device” may refer to a mobile phone, a cellular phone, a Personal Digital Assistant (PDA) equipped with radio communication capabilities, a smart phone, a laptop or Personal Computer (PC) equipped with an internal or external mobile broadband modem, a tablet PC with radio communication capabilities, a target device, a device to device UE, a machine type UE or UE capable of machine to machine communication, iPAD, Customer Premises Equipment (CPE), Laptop Embedded Equipment (LEE), Laptop Mounted Equipment (LME), Universal Serial Bus (USB) dongle, a portable electronic radio communication device, a sensor device equipped with radio communication capabilities or the like. In particular, the term “UE”, the term “Station”, the term “wireless device” and the term “wireless communication device” should be interpreted as non-limiting terms comprising any type of wireless device communicating with a network node in a wireless communication system and/or possibly communicating directly with another wireless communication device. In other words, a wireless communication device may be any device equipped with circuitry for wireless communication according to any relevant standard for communication.

As used herein, the non-limiting term “network node” may refer to base stations, access points, network control nodes such as network controllers, radio network controllers, base station controllers, access controllers, and the like. In particular, the term “base station” may encompass different types of radio base stations including standardized base stations such as Node Bs (NB), or evolved Node Bs (eNB) and also macro/micro/pico radio base stations, home base stations, also known as femto base stations, relay nodes, repeaters, radio access points, Base Transceiver Stations (BTS), and even radio control nodes controlling one or more Remote Radio Units (RRU), or the like.

In the following, the general non-limiting term “communication unit” includes network nodes and/or associated wireless devices.

As used herein, the term “network device” may refer to any device located in connection with a communication network, including but not limited to devices in access networks, core networks and similar network structures. The term network device may also encompass cloud-based network devices.

It will be appreciated that the methods and devices described herein can be combined and re-arranged in a variety of ways.

For example, embodiments may be implemented in hardware, or in a combination of hardware and software for execution by suitable processing circuitry.

The steps, functions, procedures, modules and/or blocks described herein may be implemented in hardware using any conventional technology, such as discrete circuit or integrated circuit technology, including both general-purpose electronic circuitry and application-specific circuitry.

Alternatively, or as a complement, at least some of the steps, functions, procedures, modules and/or blocks described herein may be implemented in software such as a computer program for execution by suitable processing circuitry such as one or more processors or processing units.

Examples of processing circuitry includes, but is not limited to, one or more microprocessors, one or more Digital Signal Processors (DSPs), one or more Central Processing Units (CPUs), video acceleration hardware, and/or any suitable programmable logic circuitry such as one or more Field Programmable Gate Arrays (FPGAs), or one or more Programmable Logic Controllers (PLCs).

It should also be understood that it may be possible to re-use the general processing capabilities of any conventional device or unit in which the proposed technology is implemented. It may also be possible to re-use existing software, e.g. by reprogramming of the existing software or by adding new software components.

In one embodiment, a network node in a radio communication network is configured for operating with an active antenna system. The network node comprises a radio transceiver arrangement according to any of the embodiments presented above for each independent branch in the active antenna system.

In another embodiment, a user equipment is configured for operating with an active antenna system. The user equipment comprises a radio transceiver arrangement according to any of the embodiment presented above for each independent branch in the active antenna system.

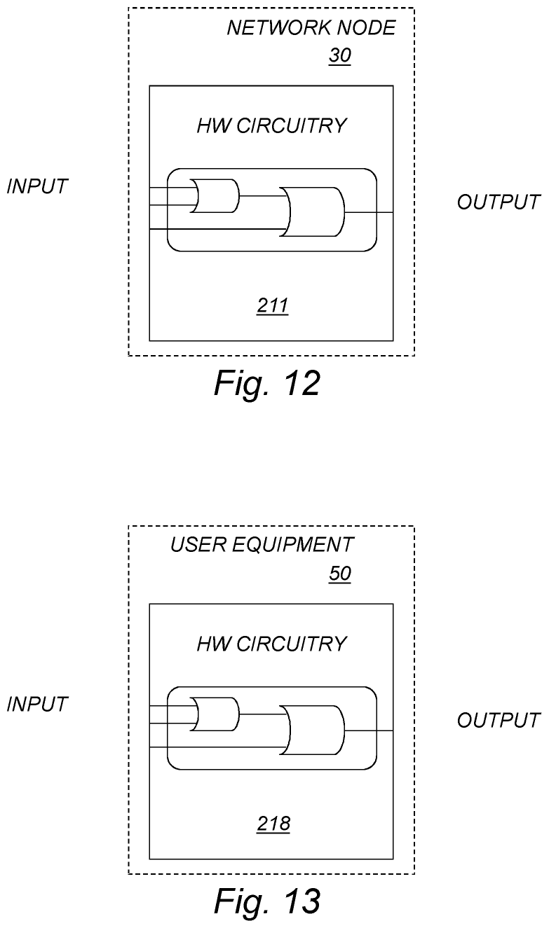

FIG. 12 is a schematic block diagram illustrating an example of a network node 30, typically a base station, based on a hardware circuitry implementation according to an embodiment. Particular examples of suitable hardware (HW) circuitry 211 include one or more suitably configured or possibly reconfigurable electronic circuitry, e.g. Application Specific Integrated Circuits (ASICs), Field Programmable Gate Arrays (FPGAs), or any other hardware logic such as circuits based on discrete logic gates and/or flip-flops interconnected to perform specialized functions in connection with suitable registers (REG), and/or memory units (MEM).

FIG. 13 is a schematic block diagram illustrating an example of a UE 50, based on a hardware circuitry implementation according to an embodiment. Particular examples of suitable hardware (HW) circuitry 218 include one or more suitably configured or possibly reconfigurable electronic circuitry, e.g. Application Specific Integrated Circuits (ASICs), Field Programmable Gate Arrays (FPGAs), or any other hardware logic such as circuits based on discrete logic gates and/or flip-flops interconnected to perform specialized functions in connection with suitable registers (REG), and/or memory units (MEM).

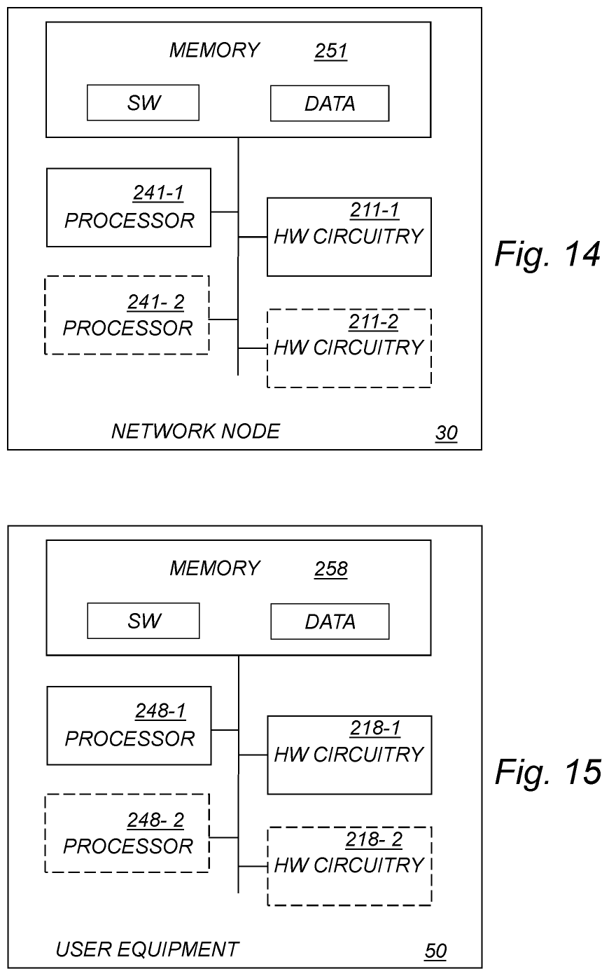

FIG. 14 is a schematic block diagram illustrating another example of a network node 30, based on combination of both processor(s) 241-1, 241-2 and hardware circuitry 211-1, 211-2 in connection with suitable memory unit(s) 251. The network node 30 comprises one or more processors 241-1, 241-2, memory 251 including storage for software and data, and one or more units of hardware circuitry 211-1, 211-2 such as ASICs and/or FPGAs. The overall functionality is thus partitioned between programmed software (SW) for execution on one or more processors 241-1, 241-2, and one or more pre-configured or possibly reconfigurable hardware circuits 211-1, 211-2 such as ASICs and/or FPGAs. The actual hardware-software partitioning can be decided by a system designer based on a number of factors including processing speed, cost of implementation and other requirements. In a preferred embodiment, the implementation of the DPD is made within the processor part and the implementation of the main TX, RX and TOR paths is made with hardware circuits.

FIG. 15 is a schematic block diagram illustrating yet another example of a UE 50, based on combination of both processor(s) 248-1, 248-2 and hardware circuitry 218-1, 218-2 in connection with suitable memory unit(s) 258. The wireless device 50 comprises one or more processors 248-1, 248-2, memory 258 including storage for software and data, and one or more units of hardware circuitry 218-1, 218-2 such as ASICs and/or FPGAs. The overall functionality is thus partitioned between programmed software (SW) for execution on one or more processors 248-1, 248-2, and one or more pre-configured or possibly reconfigurable hardware circuits 218-1, 218-2 such as ASICs and/or FPGAs. The actual hardware-software partitioning can be decided by a system designer based on a number of factors including processing speed, cost of implementation and other requirements. In a preferred embodiment, the implementation of the DPD is made within the processor part and the implementation of the main TX, RX and TOR paths is made with hardware circuits.

Alternatively, or as a complement, some of the steps, functions, procedures, modules and/or blocks described herein may be implemented in software such as a computer program for execution by suitable processing circuitry such as one or more processors or processing units.

The flow diagram or diagrams presented herein may therefore be regarded as a computer flow diagram or diagrams, when performed by one or more processors. A corresponding apparatus may be defined as a group of function modules, where each step performed by the processor corresponds to a function module. In this case, the function modules are implemented as a computer program running on the processor.

Examples of processing circuitry includes, but is not limited to, one or more microprocessors, one or more Digital Signal Processors (DSPs), one or more Central Processing Units (CPUs), video acceleration hardware, and/or any suitable programmable logic circuitry such as one or more Field Programmable Gate Arrays (FPGAs), or one or more Programmable Logic Controllers (PLCs).

It should also be understood that it may be possible to re-use the general processing capabilities of any conventional device or unit in which the proposed technology is implemented. It may also be possible to re-use existing software, e.g. by reprogramming of the existing software or by adding new software components.

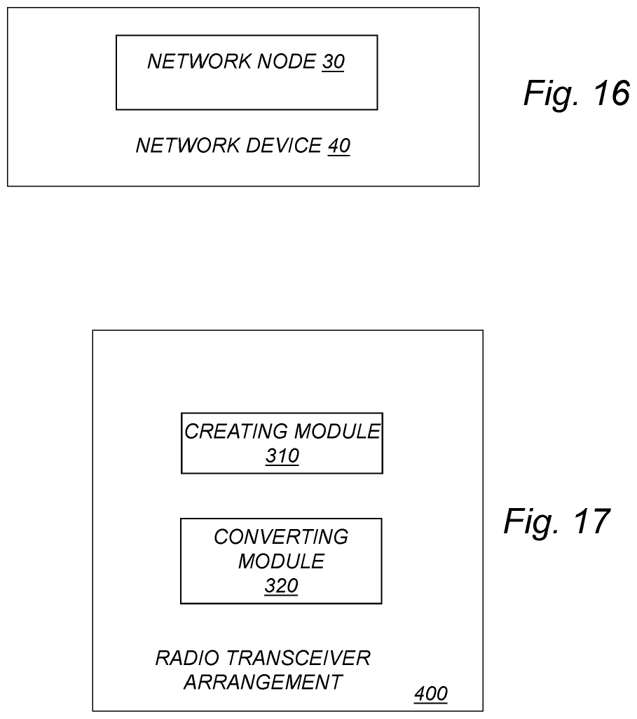

FIG. 16 is a schematic block diagram illustrating an example of a network device (ND) 40 comprising a network node 30 according to any of the embodiments.

According to an aspect, there is provided a network device 40 comprising a network node 30 as described herein.

The network device may be any suitable network device in the wireless communication system, or a network device in connection with the wireless communication system. By way of example, the network device may be a suitable network node such a base station or an access point. However, the network device may alternatively be a cloud-implemented network device.

According to another aspect, there is provided a communication unit 10 in a wireless communication system, wherein the communication unit 10 comprises a network node 30 as described herein. The communication unit may be any suitable communication unit in the wireless communication system. By way of example, the communication unit may be a wireless communication device such as a UE, STA or similar end-user device.

The flow diagram or diagrams presented herein may be regarded as a function of different modules. A corresponding apparatus may therefore be defined as a group of function modules, where each step in the methods is performed by a corresponding function module.

FIG. 17 is a schematic diagram illustrating an example of a radio transceiver arrangement 400 for performing transmission and reception of signals. The radio transceiver arrangement 400 comprises a creating module for creating a first analogue signal to be transmitted from said radio transceiver arrangement based on a digitally pre-distorted digital input signal. The radio transceiver arrangement 400 further comprises a converting module for converting a second analogue signal into a digital output signal. The second analogue signal is a combination of a received signal and a transmitter observation signal. The received signal is based on a radio signal received by the radio transceiver arrangement. The transmitter observation signal is based on a tapped signals of the first analogue signal to be transmitted from the radio transceiver arrangement. The digitally pre-distortion of the digital input signal is adapted based on the part of the output digital signal that corresponds to the transmitter observation signal.

It is possible to realize the modules in FIG. 17 predominantly by hardware modules, or alternatively entirely by hardware, with suitable interconnections between relevant modules. The extent of software versus hardware is purely implementation selection.

The embodiments described above are merely given as examples, and it should be understood that the proposed technology is not limited thereto. It will be understood by those skilled in the art that various modifications, combinations and changes may be made to the embodiments without departing from the present scope as defined by the appended claims. In particular, different part solutions in the different embodiments can be combined in other configurations, where technically possible.

### ABBREVIATIONS

5G Fifth Generation
AAS Active Antenna System
ADC Analog Digital Conversion
AFE Analog Front End
ASIC Application Specific Integrated Circuits
BPF Band Pass Filter
BTS Base Transceiver Stations
CD Compact Disc
CPE Customer Premises Equipment
CPU Central Processing Units
DAC Digital Analog Conversion
DPD Digital Pre-Distortion
DSP Digital Signal Processors
DVD Digital Versatile Disc
eNB evolved Node B
FDD Frequency Division Duplex
FPGA Field Programmable Gate Arrays
HDD Hard Disk Drive
HW hardware
IF Intermediate Frequency
I/O input/output
LEE Laptop Embedded Equipment
LME Laptop Mounted Equipment
LPF Low Pass Filter
LTE Long-Term Evolution
MEM memory units
NB Node B
ND Network Device
NR New Radio
NSD Noise spectral density
PA Power Amplifier
PAR Peak to Average Ratio
PC Personal Computer
PDA Personal Digital Assistant
PLC Programmable Logic Controllers
RAM Random Access Memory
REG registers
RF Radio Frequency
ROM Read-Only Memory
RRU Remote Radio Units
RX Receiver
STA Station
SW software
TDD Time Division Duplex
TOR Transmitter Observation Receiver
TX Transmitter
UE User Equipment
USB Universal Serial Bus
WB Wide band

1. A method for performing transmission and reception of signals in a radio transceiver arrangement, the method comprising:
creating a first analogue signal to be transmitted from the radio transceiver arrangement based on a digitally predistorted digital input signal;
converting a second analogue signal into a digital output signal;
the second analogue signal is being a combination of a received signal and a transmitter observation signal;
the received signal being based on a radio signal received by the radio transceiver arrangement;
the transmitter observation signal is being based on a tapped signal of the first analogue signal to be transmitted from the radio transceiver arrangement; and
the digital predistortion of the digital input signal being adapted based on the part of the output digital signal that corresponds to the transmitter observation signal.

2. The method according to claim 1, wherein the radio transceiver arrangement operates with frequency division duplex.

3. The method according to claim 2, wherein a frequency division duplex distance that is large enough for the transmitter observation signal and the received signal not to overlap in the frequency domain.

4. The method according to claim 2, wherein the converting comprises direct radio frequency sampling of both the transmitter observation signal and the analogue received signal.

5. The method according to claim 2, characterized by further comprising the further step of:
shifting the transmitter observation signal in frequency range compared to the first analogue signal to be transmitted from the radio transceiver arrangement.

6. The method according to claim 5, wherein the shifting is a heterodyne shifting.

7. The method according to claim 1, wherein the received signal and the transmitter observation signal are filtered to suppress aliasing products of the combination of the received signal and the transmitter observation signal.

8. The method according to claim 1, wherein the creating and converting steps are performed for each independent branch in an active antenna system.

9. The method according to claim 1, wherein creating the first analogue signal and converting the second analogue signal into the digital output signal are performed in one of a network node of a radio communication network and a user equipment.

10. (canceled)

11. A radio transceiver arrangement, configured to:
create a first analogue signal to be transmitted from the radio transceiver arrangement based on a digitally predistorted digital input signal;
convert a second analogue signal into a digital output signal;
the second analogue signal is being a combination of a received signal and a transmitter observation signal;
the received signal being based on a radio signal received by the radio transceiver arrangement;
the transmitter observation signal being based on a tapped signal of the first analogue signal to be transmitted from the radio transceiver arrangement; and
the digital predistortion of the digital input signal being adapted based on the part of the output digital signal that corresponds to the transmitter observation signal.

12. The radio transceiver arrangement according to claim 11, comprising:
a digital-to-analogue converter having an input for the digitally predistorted digital input signal;
a power amplifier one of directly and indirectly connected to an output of the digital-to-analogue converter, wherein the power amplifier has an output for the first analogue signal; and
an analogue-to-digital converter having an input for the second analogue signal and an output for the digital output signal.

13. The radio transceiver arrangement according to claim 11, wherein the radio transceiver arrangement operates with frequency division duplex.

14. The radio transceiver arrangement according to claim 13, wherein a frequency division duplex distance is large enough for the transmitter observation signal and the received signal not to overlap in the frequency domain.

15. The radio transceiver arrangement according to claim 13, wherein the converting comprises direct radio frequency sampling of both the transmitter observation signal and the received signal.

16. The radio transceiver arrangement according to claim 13, comprising a frequency shifter configured to shift the transmitter observation signal in frequency range compared to the first analogue signal to be transmitted from the radio transceiver arrangement.

17. The radio transceiver arrangement according to claim 16, wherein the frequency shifter is a heterodyne shifter.

18. The radio transceiver arrangement according to claim 11, comprising one of:
filters filtering the received signal and the transmitter observation signal to suppress aliasing products of the combination of the received signal and the transmitter observation signal; and
a digital predistorter, having an input for a digital input signal to be transmitted from the radio transceiver arrangement, and having an output for the digitally predistorted digital input signal and an input for the part of the output digital signal that corresponds to the transmitter observation signal.

19. (canceled)

20. A network node in a radio communication network, the network node being configured to operate with an active antenna system, the network node comprising, for each independent branch in the active antenna system, a radio transceiver arrangement, each radio transceiver arrangement being configured to:
create a first analogue signal to be transmitted from the radio transceiver arrangement based on a digitally predistorted digital input signal;
convert a second analogue signal into a digital output signal;
the second analogue signal being a combination of a received signal and a transmitter observation signal;
the received signal being based on a radio signal received by the radio transceiver arrangement;
the transmitter observation signal being based on a tapped signal of the first analogue signal to be transmitted from the radio transceiver arrangement; and
the digital predistortion of the digital input signal being adapted based on the part of the output digital signal that corresponds to the transmitter observation signal.

21. A user equipment, the user equipment being configured to operate with an active antenna system, the user equipment comprising, for each independent branch in the active antenna system, a radio transceiver arrangement, each radio transceiver arrangement being configured to:
create a first analogue signal to be transmitted from the radio transceiver arrangement based on a digitally predistorted digital input signal;
convert a second analogue signal into a digital output signal;
the second analogue signal being a combination of a received signal and a transmitter observation signal;
the received signal being based on a radio signal received by the radio transceiver arrangement;
the transmitter observation signal being based on a tapped signal of the first analogue signal to be transmitted from the radio transceiver arrangement; and
the digital predistortion of the digital input signal being adapted based on the part of the output digital signal that corresponds to the transmitter observation signal.
